(19) United States
(12) Patent Application Publication
(10) Pub. No.: US 2022/0077004 A1
(43) Pub. Date: Mar. 10, 2022

(54) SEMICONDUCTOR DEVICE MEASUREMENT METHOD

(71) Applicant: Changxin Memory Technologies, Inc., Hefei City (CN)

(72) Inventor: Hongxiang Li, Hefei City (CN)

(21) Appl. No.: 17/455,479

(22) Filed: Nov. 18, 2021

Related U.S. Application Data
(63) Continuation of application No. PCT/CN2021/090088, filed on Apr. 27, 2021.

(30) Foreign Application Priority Data
Apr. 28, 2020 (CN) 202010349457.9

(51) Int. Cl. H01L 21/66; G01N 21/21

(52) U.S. Cl. CPC H01L 22/12; G01N 21/211; H01L 22/30

(57) ABSTRACT

The present disclosure relates to a semiconductor device measure method, which can reduce measurement errors during the critical dimension measurement of a semiconductor device. The semiconductor device measurement method for using an OCD ellipsometer to measure critical dimensions of a semiconductor device includes the following steps: obtaining at least two minimum repeating units on a surface of the semiconductor device according to surface morphological features of a standard product of the semiconductor device; performing critical dimension measurement on the at least two minimum repeating units to obtain critical dimension data of the at least two minimum repeating units; constructing, in the OCD ellipsometer, a measurement model for the semiconductor device according to the critical dimension data of the at least two minimum repeating units; and performing critical dimension measurement on the semiconductor device by using the measure model.

### CROSS-REFERENCE TO RELATED APPLICATIONS

This application is a continuation application of International Patent Application No. PCT/CN2021/090088, filed on Apr. 27, 2021, which claims priority to Chinese Patent Application No. 202010349457.9, filed with the Chinese Patent Office on Apr. 28, 2020 and entitled “SEMICONDUCTOR DEVICE MEASUREMENT METHOD.” International Patent Application No. PCT/CN2021/090088 and Chinese Patent Application No. 202010349457.9 are incorporated herein by reference in their entireties.

### TECHNICAL FIELD

The present disclosure relates to the field of semiconductor device measurement, and in particular to a semiconductor device measurement method.

### BACKGROUND

In the production process of semiconductor devices, it is often necessary to measure the critical dimensions of the produced devices, and the more accurate the measurement data, the higher the production yield. Therefore, accurate critical dimension measurement methods for semiconductor devices have always been the pursuit of those skilled in the art.

An OCD (Optical Critical Dimension) ellipsometer is often used to measure critical dimensions in the production process of semiconductor devices. It has the advantages of high speed, high accuracy, good stability, and no damage to semiconductor devices.

In use of the OCD ellipsometer to measure the critical dimensions of semiconductor devices, measurement errors may also occur.

### SUMMARY

The present disclosure is intended to provide a semiconductor device measurement method, which can reduce measurement errors in measurement of critical dimensions of semiconductor devices and reduce the difficulty in model establishment.

There is provided a semiconductor device measurement method for using an OCD ellipsometer to measure the critical dimensions of a semiconductor device as follows. The method includes the following steps: obtaining at least two minimum repeating units on a surface of the semiconductor device according to surface morphological features of a standard product of the semiconductor device; performing critical dimension measurement on the at least two minimum repeating units to obtain critical dimension data of the at least two minimum repeating units; constructing, in the OCD ellipsometer, a measurement model for the semiconductor device according to the critical dimension data of the at least two minimum repeating units; and performing critical dimension measurement on the semiconductor device by using the measure model.

### BRIEF DESCRIPTION OF DRAWINGS

In order to more clearly illustrate the technical solutions in the embodiments of the present disclosure, the accompanying drawings required to be used in the description of the embodiments will be briefly introduced below. Apparently, the accompanying drawings in the following description merely show some embodiments of the present disclosure, and persons of ordinary skill in the art may still derive other drawings from these accompanying drawings without creative efforts.

FIG. 1 is a schematic step flowchart of a semiconductor device measurement method according to an embodiment of the present disclosure.

FIG. 2 is a slice view of silicon dioxide etched at spacing regions of different lengths according to an embodiment of the present disclosure.

FIG. 3A is a schematic top view of a memory device according to an embodiment of the present disclosure before an embedded wordline etching step.

FIG. 3B and FIG. 3C are schematic diagrams of an analog structure of a minimum repeating unit formed by a longer spacing region between two adjacent active regions and the active region according to an embodiment of the present disclosure before a memory device is subjected to an embedded wordline etching step, in which FIG. 3C is a cross-sectional view.

FIG. 3D and FIG. 3E are schematic diagrams of an analog structure of a minimum repeating unit formed by a shorter spacing region between two adjacent active regions and the active region according to an embodiment of the present disclosure before a memory device is subjected to an embedded wordline etching step, in which FIG. 3E is a cross-sectional view.

FIG. 4A is a schematic top view of a memory device according to an embodiment of the present disclosure after an embedded wordline etching step.

FIG. 4B and FIG. 4C are schematic diagrams of an analog structure of a minimum repeating unit formed by a longer spacing region between two adjacent active regions and the active region according to an embodiment of the present disclosure after a memory device is subjected to an embedded wordline etching step.

FIG. 4D and FIG. 4E are schematic diagrams of an analog structure of a minimum repeating unit formed by a shorter spacing region between two adjacent active regions and the active region according to an embodiment of the present disclosure after a memory device is subjected to an embedded wordline etching step.

FIG. 5A and FIG. 5B show comparison trend diagrams and linear relationship diagrams of measurement results obtained by using dicing measurement of two structures; diagrams at top in both FIG. 5A and FIG. 5B are comparison trend diagrams, and diagrams at bottom in both FIG. 5A and FIG. 5B are linear relationship diagrams, where a first broken line indicates dicing SEM (Scanning Electron Microscopy) measurement results of an embedded wordline trench in a memory array formed on a silicon thin film or a silicon dioxide thin film to be measured actually, a second broken line indicates dicing SEM measurement results of an embedded wordline trench in an analog structure formed on an experimental silicon thin film or an experimental silicon dioxide thin film in the present disclosure, and an embedded wordline trench of a first analog structure corresponding to a first minimum repeating unit and an embedded wordline trench of a second analog structure corresponding to a second minimum repeating unit are included.

FIG. 6A to FIG. 6D are schematic diagrams of the linear relationship between dicing SEM measurement data of analog structures obtained by a measurement model constructed in an embodiment of the present disclosure and measurement data obtained by using an OCD ellipsometer, where a first analog structure and a second analog structure in FIGS. 6A and 6B are formed on an experimental silicon thin film, and a first analog structure and a second analog structure in FIGS. 6C and 6D are formed on an experimental silicon dioxide thin film.

FIG. 6E and FIG. 6 F are graphs of data used in FIG. 6A to FIG. 6D.

### DESCRIPTION OF EMBODIMENTS

According to a study, during critical dimension measurement of a semiconductor device by using an OCD ellipsometer, the semiconductor device is considered as a distributed arrangement of a plurality of minimum repeating units, and the accuracy of a measurement model constructed for the minimum repeating unit is limited. For a semiconductor device with more complex morphological features, the use of the same minimum repeating unit is often not a good description of the semiconductor device. Therefore, in the critical dimension measurement of the semiconductor device with more complex morphological features, the current measurement method will cause a large deviation. That is the reason for measurement errors in the critical dimension measurement of a semiconductor device by using an OCD ellipsometer. However, establishment of a high-accuracy measurement mode is time-consuming and will cause a sharp increase in modeling difficulty.

For example, for forming an embedded wordline, a silicon dioxide layer is first filled on the basis of an active region, and then trenches are etched in the surface of the silicon dioxide layer to form the embedded wordline. Due to different line widths of spacing regions between the trenches, the depths of the trenches actually etched are different during etching, but since only the same minimum repeating unit is used to measure the depths of the trenches, a measurement error in trench depth tends to occur.

In order to more clearly illustrate the objective, technical means and effects of the present disclosure, the present disclosure will be further elaborated below in conjunction with the accompanying drawings. It should be understood that embodiments described here are only a part of, not all the embodiments of the present disclosure and not intended to limit the present disclosure. All other embodiments obtained by a person of ordinary skill in the art based on the embodiments of the present disclosure without creative efforts shall fall within the protection scope of the present disclosure.

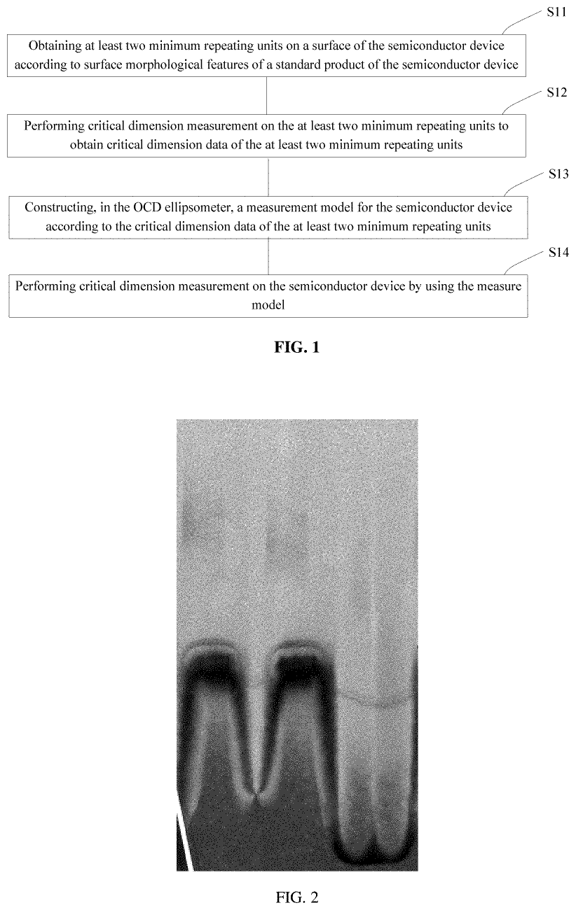

Referring to FIG. 1, a schematic step flowchart of a semiconductor device measurement method according to an embodiment of the present disclosure is illustrated.

In the embodiment shown in FIG. 1, there is provided a semiconductor device measurement method for using an OCD ellipsometer to measure the critical dimensions of a semiconductor device. The method includes the following steps: S11, obtaining at least two minimum repeating units on a surface of the semiconductor device according to surface morphological features of a standard product of the semiconductor device; S12, performing critical dimension measurement on the at least two minimum repeating units to obtain critical dimension data of the at least two minimum repeating units; S13, constructing, in the OCD ellipsometer, a measurement model for the semiconductor device according to the critical dimension data of the at least two minimum repeating units; and S14, performing critical dimension measurement on the semiconductor device by using the measure model.

The semiconductor device measurement method in this embodiment can divide the semiconductor device into at least two minimum repeating units according to the morphological features of the standard product of the semiconductor device, which facilitates the construction of a more accurate measurement model for a semiconductor device with complex morphologies, thereby obtaining more accurate critical dimension data. In addition, using the semiconductor device measurement method in this embodiment can effectively reduce the adverse effect of the complex morphological features of the semiconductor device on the measurement accuracy. Moreover, in use of the semiconductor device measurement method in this embodiment, there is a little difficulty in constructing a measurement model, and the measurement accuracy is high.

In this embodiment, a production standard of the semiconductor device may be embodied on the standard product. Constructing a measurement model for the semiconductor device by analyzing the standard product can make the measurement model more universal.

In one embodiment, when constructing, in the OCD ellipsometer, a measurement model for the semiconductor device according to the critical dimension data of the at least two minimum repeating units, the method further includes the following steps: forming, on a thin film, a plurality of analog structures with the same critical dimension data as each minimum repeating unit; using the OCD ellipsometer to perform critical dimension measurement on the analog structures to obtain first critical dimension data; using the OCD ellipsometer to perform critical dimension measurement on the standard product to obtain second critical dimension data; and obtaining, in the OCD ellipsometer, a measurement model for the standard product according to the first critical dimension data and the second critical dimension data.

In this embodiment, the OCD ellipsometer can emit ellipsometric light to measure standard dimensions of the analog structure and standard dimensions of the standard product to be measured, and construct a measurement model required for the measurement using these measurement data. In some other embodiments, an initial measurement model may also be set in the OCD ellipsometer, and the initial measurement model is used as the basis of measurement to output more accurate measurement data.

In one embodiment, when constructing the measurement model, the OCD ellipsometer will fit a spectrum according to the constructed measurement model and fit an actual measured spectrum to adjust parameters of the measurement model so that the spectrum fitted by the measurement model tends to be consistent with the spectrum obtained by the actual measurement. In this embodiment, the spectrum obtained by actual measurement includes a spectrum obtained by actually measuring the analog structure and a spectrum obtained by actually measuring the standard product.

In this embodiment, the measurement model has been adjusted many times, so the obtained measurement model is more in line with the actual situation of the standard product.

In one embodiment, before performing critical dimension measurement on the analog structures to obtain the first critical dimension data, the method further includes the following step: performing at least one same process on the semiconductor device to be measured and each analog structure.

In this embodiment, after the analog structure undergoes at least one same process as the semiconductor device to be measured, the measurement of the first critical dimension data is performed, thereby avoiding some problems caused by the analog structure being too simple. For example, the analog structure is too simple and is quite different in structure from the actual semiconductor device to be measured, so the analog structure cannot well reflect the critical dimensions of the semiconductor device to be measured.

In one embodiment, when the semiconductor device serves as a memory device and a measurement region serves as a memory array of the memory device, the analog structure is implemented in a dicing lane of a wafer on which the memory device is formed. An environment in the dicing lane is relatively simple, which is quite different from an actual environment in which the standard product is located. Therefore, even if the analog structure is measured, the actual situation of the standard product cannot be well reflected. The analog structure does not match the actual memory array well.

After the analog structure and the semiconductor device to be measured are put into at least one same subsequent production process, since the analog structure has more similar parts to the semiconductor device to be measured, the first critical dimension data that is closer to the actual critical dimension data can be obtained.

In one embodiment, the thin film includes at least one of a silicon thin film, a silicon nitride thin film, and a silicon dioxide thin film. In another embodiment, the analog structure is formed in a dicing lane of a wafer on which the standard product is formed. For example, when the semiconductor device serves as a wafer on which a memory device is to be formed, the analog structure can be formed in the dicing lane of the wafer.

In one embodiment, when obtaining the at least two minimum repeating units on the surface of the semiconductor device according to the surface morphological features of the standard product of the semiconductor device, the method includes the following steps: obtaining surface topography characteristic data of the standard product of the semiconductor device, the data including line widths of different regions on a surface of the standard product and a distribution mode of different line widths; and determining regions with similar line widths as the same minimum repeating unit.

In this embodiment, different minimum repeating units are divided according to the line widths of different regions on the surface of the standard product and the distribution mode of different line widths, and regions of different line widths are analyzed separately, which can effectively avoid an interference effect caused by the different line widths of different regions on the surface of the standard product.

In one embodiment, when determining regions with similar line widths as the same minimum repeating unit, the method comprises the following steps: determining whether a line width of a selected region is within a preset line width range, and if so, determining that the region is a minimum repeating unit corresponding to the preset line width range. In an embodiment, the preset line width range can be set by a user as needed. Generally, during construction of a measurement model for a memory array of a memory device, two minimum repeating units are constructed. Specifically, a region with a line width in the range of 20 nm to 50 nm is determined as a first minimum repeating unit, and a region with a line width in the range of 40 nm to 80 nm is determined as a second minimum repeating unit. In fact, the line width range of the minimum repeating unit can also be determined as needed. Generally, the smaller the line width range of the minimum repeating unit, the more accurate the measurement model finally obtained.

In an embodiment, before determining regions with similar line widths as the same minimum repeating unit, the method further includes the following step: determining at least two preset line width ranges to obtain at least two minimum repeating units. In actual use, the line width range of each minimum repeating unit can be determined as needed. A reasonable line width range is set for each minimum repeating unit, which effectively avoids the interference effect of optical signals caused by the different line widths of various regions in the minimum repeating unit during OCD measurement.

In one embodiment, the critical dimensions of the semiconductor device and the analog structure are measured using light with a wavelength of 190 nm to 860 nm. In one embodiment, yellow light is used to measure the critical dimensions of the semiconductor device and the analog structure.

In one embodiment, when performing critical dimension measurement on the semiconductor device by using the measure model, the method includes the following steps: projecting a measurement light to the semiconductor device to be measured; obtaining an interference spectrum formed by the semiconductor device reflecting the measurement light; and carrying out comparison analysis between the interference spectrum and the measurement model to obtain critical dimensions of the semiconductor device.

In one embodiment, comparison analysis is carried out between the measurement model and the interference spectrum of each minimum repeating unit on the semiconductor device.

### Embodiment

In the embedded wordline etching step process, the active regions are arranged in an overlapping manner, resulting in different line widths of spacing regions between every two adjacent active regions, and silicon dioxide is formed between two adjacent active regions. In the process of forming an embedded wordline, the silicon dioxide between two adjacent active regions needs to be etched to form an embedded wordline trench.

Since in the formed memory device, the spacing regions between every two adjacent active regions are different in line width, these different line widths will result in different depths of the embedded wordline trenches formed after the silicon dioxide at these spacing regions is etched. During measurement of the depth of the embedded wordline trench by using a conventional OCD measurement method, since the same minimum repeating unit is used for measurement and the line width difference between two adjacent active regions is ignored, the embedded wordline trenches present similar optical signals with low discrimination when being measured, thus causing inaccurate analysis results.

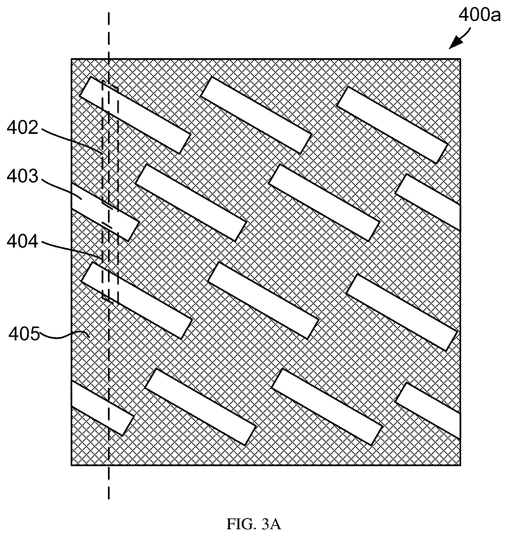

Referring to FIG. 2, a slice view of a memory array of a memory device in a wordline direction is illustrated According to SEM, it can be seen that when the embedded wordline trenches are formed, the embedded wordline trenches formed have different depths. This is because of the different sizes of the spacing regions between every two adjacent trenches, wherein a shorter trench corresponds to a spacing region, and a longer trench corresponds to a longer spacing region.

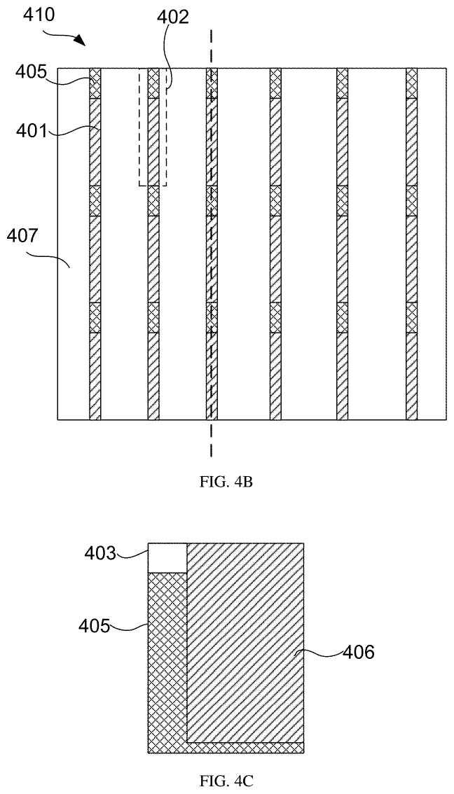

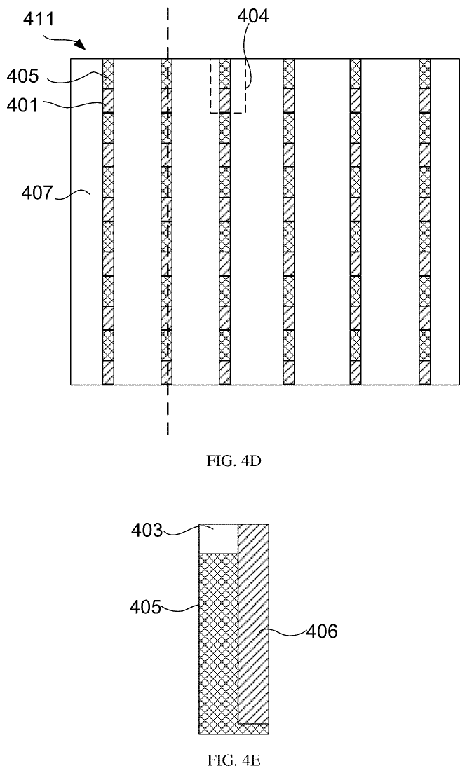

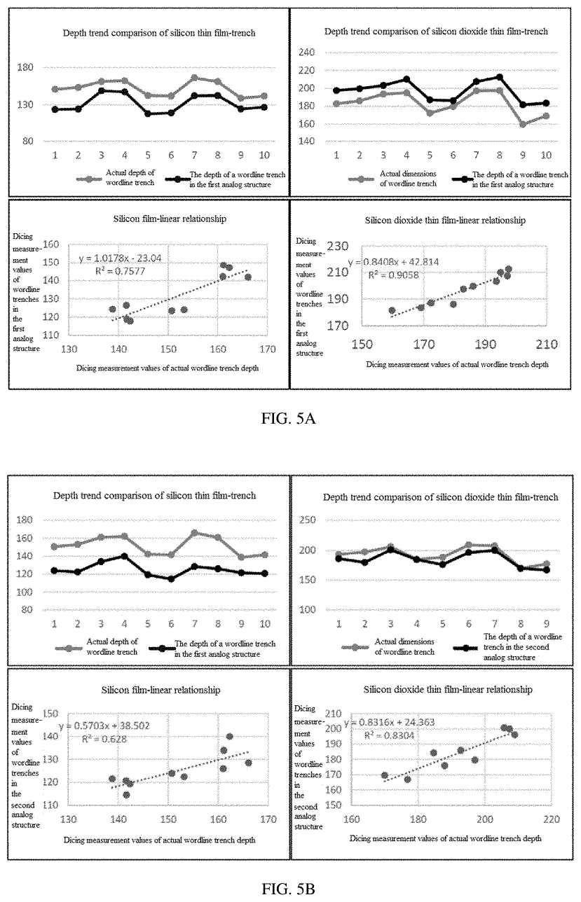

In this embodiment, in application of the semiconductor device measurement method, the memory array of the memory device is divided into two minimum repeating units, and the two minimum repeating units are embodied on a thin film to form analog structures. Specifically, reference may be made to FIG. 4A to FIG. 4E, including a first minimum repeating unit 402 and a second minimum repeating unit 404; FIG. 4B and FIG. 4C show an analog structure 410 corresponding to the first minimum repeating unit 402, and FIG. 4D and FIG. 4E show an analog structure 411 corresponding to the second minimum repeating unit 404.

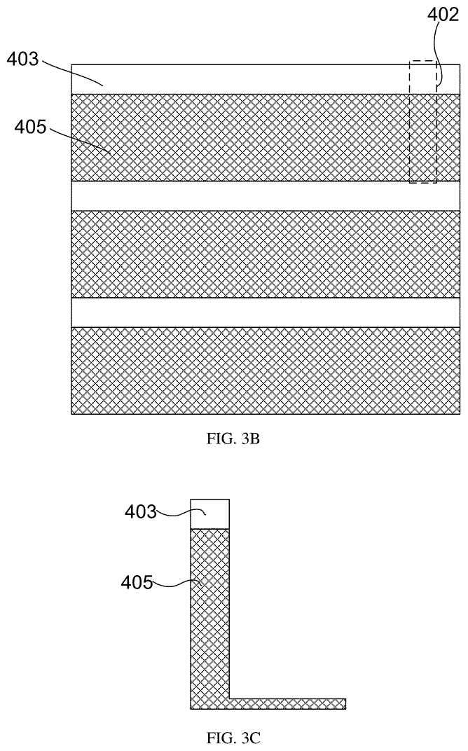

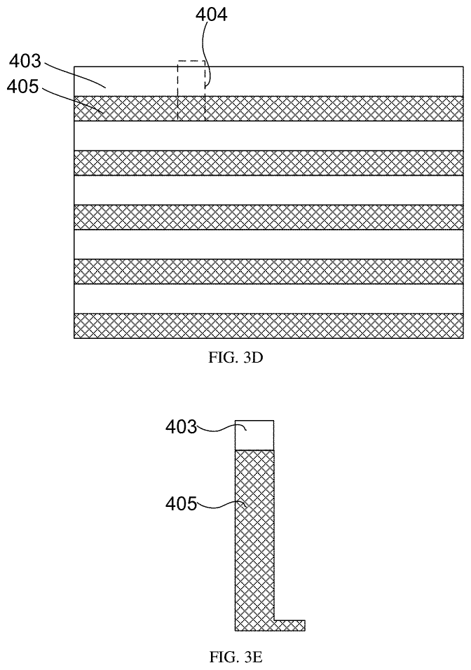

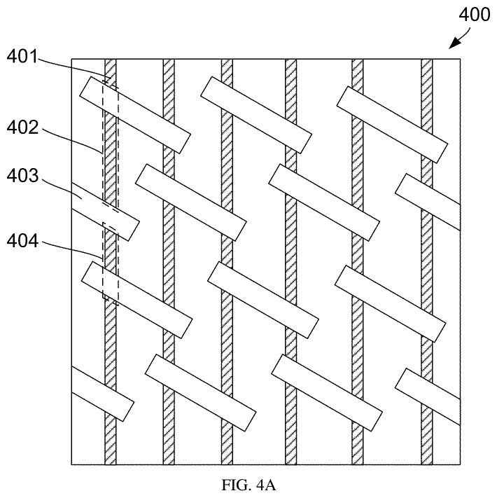

From FIG. 3A to FIG. 3E, then to FIG. 4A to FIG. 4E, the analog structure undergoes the process flow, including the formation of a silicon dioxide layer 406 in isolation trenches in the substrate 405 to fill up the isolation trenches and the formation of an active region 403 above the silicon dioxide layer 406. In meanwhile, the same processing is performed on the memory device to be measured, so that the analog structure shown in FIG. 4A to FIG. 4E obtained later has more similar parts to the structure of the actual memory device to be measured, thus ensuring a high similarity between finally obtained first critical dimension data and second critical dimension data.

Specifically, FIG. 3A corresponds to FIG. 4A; FIGS. 3B and 3C correspond to FIGS. 4B and 4C; FIG. 3D and FIG. 3E correspond to FIGS. 4D and 4E; FIGS. 3B and 3D are both top views of the analog structure; and the FIGS. 3C and 3E are both cross-sectional views of the analog structure, cut along dashed lines in FIG. 3B and FIG. 3D.

In this embodiment, the dimension of the analog structure 410 corresponding to the first minimum repeating unit 402 is a sum of the width of the active region 403 and the dimension of a wider spacing region between two adjacent active regions 403, and the dimension of the analog structure 411 corresponding to the second minimum repeating unit 404 is a sum of the width of the active region 403 and the dimension of a narrower spacing region between two adjacent active regions 403.

In formation of embedded wordline trenches in the surface of the analog structure 410 corresponding to the first minimum repeating unit 402 and the surface of the analog structure 411 corresponding to the second minimum repeating unit 404, the measured depth of the embedded wordline trench has a good linear relationship with the depth of the actual embedded wordline trench, indicating that the depth of the actual embedded wordline trench can be accurately simulated. In addition, because the regions with different line widths are regarded as different minimum repeating units for analysis, for the same minimum repeating unit, there is no signal interference caused by a large line width difference, which also improves the accuracy of OCD measurement.

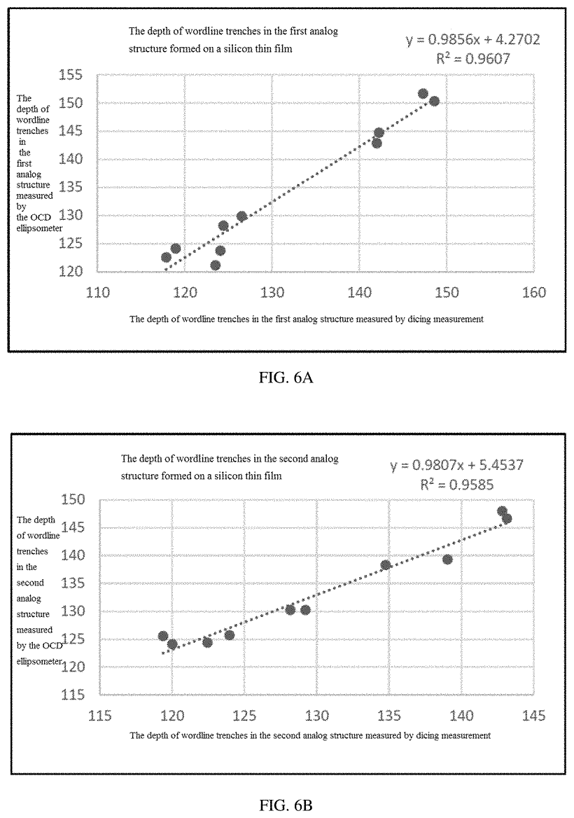

Referring to FIG. 5A and FIG. 5B, comparison trend diagrams and linear relationship diagrams of measurement results obtained by using dicing SEM measurement of two structures are illustrated diagrams at top in both FIG. 5A and FIG. 5B are comparison trend diagrams, and diagrams at bottom in both FIG. 5A and FIG. 5B are linear relationship diagrams, where a first broken line indicates dicing SEM (Scanning Electron Microscopy) measurement results of an embedded wordline trench in a memory array formed on a silicon thin film or a silicon dioxide thin film to be measured actually, a second broken line indicates dicing SEM measurement results of a wordline trench in an analog structure formed on an experimental silicon thin film or an experimental silicon dioxide thin film in the present disclosure, and an embedded wordline trench of an analog structure corresponding to a first minimum repeating unit and an embedded wordline trench of an analog structure corresponding to a second minimum repeating unit are included.

In FIG. 5A and FIG. 5B, values of R2 in all the linear relationship diagrams are greater than 0.4, which indicates a strong correlation. Therefore, the embedded wordline trench formed in the analog structure corresponding to the first minimum repeating unit and the embedded wordline trench formed in the analog structure corresponding to the second minimum repeating unit can reflect the situation of the memory array of the memory device.

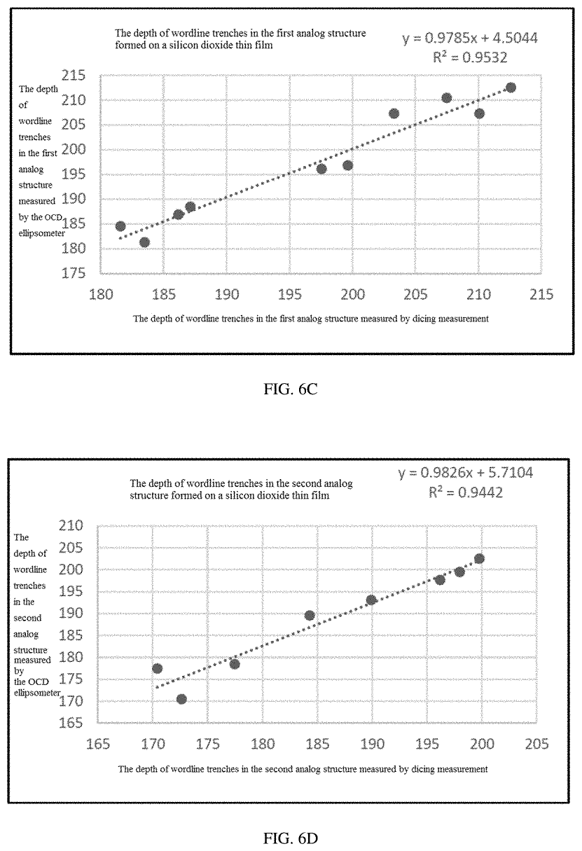

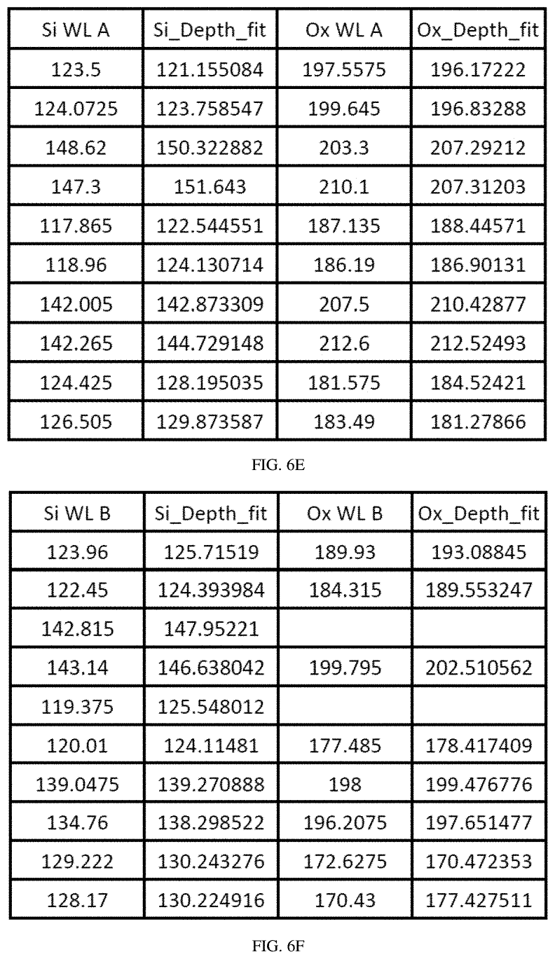

Reference can be made to FIG. 6A to FIG. 6D, which both compare the data of the wordline trench of an analog structure measured by the OCD ellipsometer with the data of the wordline trench of the analog structure measured by the dicing SEM. The correlation shows that the data measured by the OCD ellipsometer can accurately reflect the dimensions of the analog structure, and combined with FIG. 5A and FIG. 5B, it further shows that the data of the analog structure measured by the OCD ellipsometer can reflect the dimension data of the trench to be measured actually.

FIG. 6E and FIG. 6F are graphs of data used in FIG. 6A to FIG. 6D. It can be seen from FIG. 6A to FIG. 6D that when the measurement model constructed in the measurement method is used to measure the embedded wordline trench formed in the analog structure corresponding to the first minimum repeating unit, and the embedded wordline trench formed in the analog structure corresponding to the second minimum repeating unit, the results of both have a good linear correlation with their results obtained by SEM measurement. Reference may be made to FIG. 6E and FIG. 6F. In FIG. 6E and FIG. 6F, Si WL A and Si WL B respectively represent the values (corresponding to the abscissae in FIG. 6A and FIG. 6B respectively) of embedded wordline trenches actually measured by dicing SEM, wherein the embedded wordline trenches are formed in analog structures corresponding to a first minimum repeating unit and a second minimum repeating unit on a silicon substrate; Si_Depth_fit respectively represents the values (corresponding to the ordinates in FIG. 6A and FIG. 6B respectively) of embedded wordline trenches measured by the OCD ellipsometer, wherein the embedded wordline trenches are formed in analog structures corresponding to a first minimum repeating unit and a second minimum repeating unit on a silicon substrate; Si Ox WL A and Ox WL B respectively represent the values (corresponding to the abscissae in FIG. 6C and FIG. 6D respectively) of embedded wordline trenches actually measured by dicing SEM, wherein the embedded wordline trenches are formed in analog structures corresponding to a first minimum repeating unit and a second minimum repeating unit on a silicon dioxide substrate; and Ox_Depth_fit respectively represents the values (corresponding to the ordinates in FIG. 6C and FIG. 6D respectively) of embedded wordline trenches measured by the OCD ellipsometer, wherein the embedded wordline trenches are formed in analog structures corresponding to a first minimum repeating unit and a second minimum repeating unit on a silicon dioxide substrate.

The above are only the preferred embodiments of the present disclosure. It should be noted that for those of ordinary skill in the art, without departing from the principle of the present disclosure, several improvements and modifications can be made, and these improvements and modifications also should be considered as falling within the protection scope of the present disclosure.

What is claimed is:

1. A semiconductor device measurement method for using an Optical Critical Dimension ellipsometer to measure critical dimensions of a semiconductor device, including the following steps:
obtaining at least two minimum repeating units on a surface of the semiconductor device according to surface morphological features of a standard product of the semiconductor device;
performing critical dimension measurement on the at least two minimum repeating units to obtain critical dimension data of the at least two minimum repeating units;
constructing, in the Optical Critical Dimension ellipsometer, a measurement model for the semiconductor device according to the critical dimension data of the at least two minimum repeating units; and
performing critical dimension measurement on the semiconductor device by using the measure model.

2. The semiconductor device measurement method according to claim 1, wherein when constructing, in the Optical Critical Dimension ellipsometer, a measurement model for the semiconductor device according to the critical dimension data of the at least two minimum repeating units, the method further comprises the following steps:
forming, on a thin film, a plurality of analog structures with the same critical dimension data as each minimum repeating unit;
using the Optical Critical Dimension ellipsometer to perform critical dimension measurement on the analog structures to obtain first critical dimension data;
using the Optical Critical Dimension ellipsometer to perform critical dimension measurement on the standard product to obtain second critical dimension data; and
obtaining, in the Optical Critical Dimension ellipsometer, a measurement model for the standard product according to the first critical dimension data and the second critical dimension data.

3. The semiconductor device measurement method according to claim 2, wherein before performing critical dimension measurement on the analog structures to obtain the first critical dimension data, the method further comprises the following step:
performing at least one same process on the semiconductor device to be measured and each analog structure.

4. The semiconductor device measurement method according to claim 2, wherein the thin film comprises at least one of a silicon thin film, a silicon nitride thin film, and a silicon dioxide thin film.

5. The semiconductor device measurement method according to claim 2, wherein the analog structure is formed in a dicing lane of a wafer on which the standard product is formed.

6. The semiconductor device measurement method according to claim 1, wherein when obtaining at least two minimum repeating units on a surface of the semiconductor device according to surface morphological features of a standard product of the semiconductor device, the method further comprises:
obtaining surface topography characteristic data of the standard product of the semiconductor device, the surface topography characteristic data comprising line widths of different regions on a surface of the standard product and a distribution mode of different line widths; and
determining regions with similar line widths as the same minimum repeating unit.

7. The semiconductor device measurement method according to claim 6, wherein when determining regions with similar line widths as the same minimum repeating unit, the method further comprises the following steps: determining whether a line width of a selected region is within a preset line width range, and if so, determining that the region is a minimum repeating unit corresponding to the preset line width range.

8. The semiconductor device measurement method according to claim 6, wherein before determining regions with similar line widths as the same minimum repeating unit, the method further comprises the following step:
determining at least two preset line width ranges to obtain at least two minimum repeating units.

9. The semiconductor device measurement method according to claim 1, wherein when performing critical dimension measurement on the semiconductor device by using the measure model, the method comprises the following steps:
projecting a measurement light to the semiconductor device to be measured;
obtaining an interference spectrum formed by the semiconductor device reflecting the measurement light; and
carrying out comparison analysis between the interference spectrum and the measurement model to obtain critical dimensions of the semiconductor device.

10. The semiconductor device measurement method according to claim 1, further comprising the following step: carrying out comparison analysis between the measurement model and an interference spectrum of each minimum repeating unit on the semiconductor device.
